(19) United States
(12) Patent Application Publication
(10) Pub. No.: US 2002/0197742 A1
(43) Pub. Date: Dec. 26, 2002

(54) Method of forming smooth polycrystalline silicon electrodes for molecular eletronic devices

(76) Inventor: Theodore I. Kamins, Palo Alto, CA (US)

Correspondence Address: HEWLETT-PACKARD COMPANY, Intellectual Property Administration, P.O. Box 272400, Fort Collins, CO, 80527-2400, US

(21) Appl. No.: 09/891,491

(22) Filed: Jun. 25, 2001

(51) Int. Cl. H01L 21/00

(52) U.S. Cl. 438/1; 438/486; 438/684

(57) ABSTRACT

A method is provided for forming smooth polycrystalline silicon electrodes for molecular electronic devices. The method comprises: (a) depositing a silicon layer in an amorphous form; (b) forming a native oxide on a surface of the amorphous silicon layer; and (c) converting the amorphous silicon to polycrystalline silicon by heat-treating at a temperature in a range of 600° to 1000° C. for a period of time in a range of 10 secs to 24 hrs, with higher temperatures associated with shorter times, in an inert atmosphere. The method converts the amorphous form of silicon to the higher conductivity polycrystalline form, while retaining the smoothness associated with the amorphous form.

### CROSS-REFERENCE TO RELATED APPLICATIONS

The present application is related to application Ser. No. 09/280,048, entitled “Chemically Synthesized and Assembled Electronic Devices”, filed on Mar. 29, 1999, which is directed to the formation of nanowires used for nanoscale computing and memory circuits. The present application is also related to applications Ser. No. 09/280,225, entitled “Molecular Wire Crossbar Interconnect (MWCI) for Signal Routing and Communications”, Ser. No. 09/280,045, entitled “Molecular Wire Crossbar Logic (MWCL)”, and Ser. No. 09/280,188, entitled “Molecular Wire Transistor (MWT)”, all also filed on Mar. 29, 1999, and to U.S. Pat. No. 6,128,214, entitled “Molecular Wire Crossbar Memory”, issued on Oct. 3, 2000, which are all directed to various aspects of memory and logic circuits utilized in nanocomputing. The present application is also related to application Ser. No. 09/823,195, filed Mar. 29, 2001. The foregoing references are all incorporated herein by reference.

### TECHNICAL FIELD

The present application is generally directed to nanoscale computing and memory circuits, and, more particularly, to the formation of nanowires for device applications, specifically, to the fabrication of polycrystalline silicon (“polysilicon”) nanowires.

### BACKGROUND ART

With the constantly decreasing feature sizes of integrated-circuit devices, well-behaved devices are becoming increasingly difficult to design. The fabrication is also becoming increasingly difficult and expensive. In addition, the number of electrons within a device is decreasing, with increasing statistical fluctuations in the electrical properties. In the limit, device operation depends on a single electron, and traditional device concepts must change.

Molecular electronics have the potential to augment or even replace conventional devices by electronic elements, can be altered by externally applied voltages, and have the potential to scale from micron-size dimensions to nanometer-scale dimensions with little change in the device concept. The molecular switching elements can be formed by inexpensive solution techniques; see, e.g., C. P. Collier et al, “Electronically Configurable Molecular-Based Logic Gates”, Science, Vol. 285, pp. 391-394 (Jul. 16, 1999) and C. P. Collier et al, “A [2]Catenane-Based Solid State Electronically Reconfigurable Switch”, Science, Vol. 289, pp. 1172-1175 (Aug. 18, 2000). The self-assembled switching elements may be integrated on top of a Si integrated circuit so that they can be driven by conventional Si electronics in the underlying substrate. To address the switching elements, interconnections or wires are used.

Molecular electronic devices, comprising crossed wire switches, hold promise for future electronic and computational devices. Thin single or multiple atomic layers can be formed, for example, by Langmuir-Blodgett techniques. A very smooth underlying surface is needed to allow optimal LB film formation. A crossed wire switch may comprise two nanowires, or electrodes, for example, with a molecular switching species between the two electrodes.

Semiconducting electrodes, for example, silicon, are especially useful in such devices. In some cases, the electronic properties of the resulting device can be influenced by the energy band structure of the semiconducting electrode. In addition, using silicon is attractive for compatibility and interfacing with silicon integrated-circuit electronics. Polycrystalline silicon may be especially useful because it can be formed on top of and electrically isolated from the silicon substrate, which can then contain conventional electronic devices.

Therefore, a method of forming polycrystalline silicon electrodes with very smooth surfaces is needed. When polycrystalline silicon is deposited by conventional methods in the polycrystalline form, such as by low pressure chemical vapor deposition (LPCVD) at 0.2 Torr and 625° C. using SiH₄, the surface is rough because of the crystalline grains formed during the deposition process; see, e.g., M. Sternheim et al, “Properties of Thermal Oxides Grown on Phosphorus In Situ Doped Polysilicon”, Journal of Electrochemical Society, Vol. 130, No. 8, pp. 1735-1740 (Aug. 1983). If the silicon layer is deposited in the amorphous form (e.g., LPCVD at 0.2 Torr and 525° to 550° C. using SiH₄), then the surface is very smooth; see, e.g., E. Ibok et al, “A Characterization of the Effect of Deposition Temperature on Polysilicon Properties”, Journal of Electrochemical Society, Vol. 140, No. 10, pp. 2927-2937 (Oct. 1993); and T. Kamins, Polycrystalline Silicon for Integrated Circuit Applications, p. 148, Kluwer Academic, Boston, Mass. (1988).

What is needed is a process to convert the amorphous form of silicon to the more electrically conductive polycrystalline form, while retaining the smoothness associated with the amorphous form. By “smooth” herein is meant that the rms surface roughness is less than, for example, about 2% of the polycrystalline silicon film thickness.

### DISCLOSURE OF INVENTION

In accordance with the present invention, a method is provided for forming smooth polycrystalline silicon electrodes for molecular electronic devices. The method comprises:

(a) depositing a silicon layer in an amorphous form;

(b) forming a native oxide on a surface of the amorphous silicon layer;

(c) converting the amorphous silicon to polycrystalline silicon by heat-treating at a temperature in a range of 600° to 1000° C. for a period of time in a range of 10 secs to 24 hrs, with higher temperatures associated with shorter times, in an inert atmosphere.

The method of the present invention converts the amorphous form of silicon to the polycrystalline form, while retaining the smoothness associated with the amorphous form.

### BRIEF DESCRIPTION OF THE DRAWINGS

FIGS. 1a-1c are a schematic representation of the steps that use chemically fabricated (nanometer-scale diameter) wires to form a crossed wire switch; and

FIGS. 2a-2e are cross-sectional views, depicting the conversion of amorphous silicon to polycrystalline silicon and the formation of electrodes therefrom.

### BEST MODES FOR CARRYING OUT THE INVENTION

### Definitions

As used herein, the term “self-aligned” as applied to “junction” means that the junction that forms the switch and/or other electrical connection between two wires is created wherever two wires, either of which may be coated or functionalized, cross each other, because it is the act of crossing that creates the junction.

The term “self-assembled” as used herein refers to a system that naturally adopts some geometric pattern because of the identity of the components of the system; the system achieves at least a local minimum in its energy by adopting this configuration.

The term “singly configurable” means that a switch can change its state only once via an irreversible process such as an oxidation or reduction reaction; such a switch can be the basis of a programmable read-only memory (PROM), for example.

The term “reconfigurable” means that a switch can change its state multiple times via a reversible process such as an oxidation or reduction; in other words, the switch can be opened and closed multiple times, such as the memory bits in a random access memory (RAM).

The term “bi-stable” as applied to a molecule means a molecule having two relatively low energy states. The molecule may be either irreversibly switched from one state to the other (singly configurable) or reversibly switched from one state to the other (reconfigurable).

“Micron-scale dimensions” refers to dimensions that range from 1 micrometer to a few micrometers in size.

“Sub-micron scale dimensions” refers to dimensions that range from 1 micrometer down to 0.05 micrometers.

“Nanometer scale dimensions” refers to dimensions that range from 0.1 nanometers to 50 nanometers (0.05 micrometers).

“Micron-scale wires” refers to rod or ribbon-shaped conductors or semiconductors with widths or diameters having the dimensions of 1 to 10 micrometers, heights that can range from a few tens of nanometers to a micrometer, and lengths of several micrometers and longer.

“Nanometer-scale wires” refers to rod or ribbon-shaped conductors or semiconductors with widths or diameters having the dimension of 1 to 50 nanometers, heights that can range from 0.3 to 100 nanometers, and lengths up to several micrometers or more.

### Crossed Wire Switches

The description which follows is directed to the formation of micrometer scale and nanometer scale crossed wire switches, using either a reduction-oxidation (redox) reaction to form an electrochemical cell or using electric field (E-field) induced band gap changes to form molecular switches. In either case, the molecular switches typically have two states, and may be either irreversibly switched from a first state to a second state or reversibly switched from a first state to a second state. In the latter case, there are two possible conditions: (1) either the electric field may be removed after switching into a given state, and the molecule will remain in that state (“latched”) until a reverse field is applied to switch the molecule back to its previous state, or (2) removal of the electric field would cause the molecule to revert to its previous state, and hence the field must be maintained in order to keep the molecule in the switched state until it is desired to switch the molecule to its previous state.

The crossed wire switch based on the redox reaction approach is disclosed and claimed in the above-identified patent application Ser. No. 09/280,048. Examples of molecules used in the redox reaction approach include rotaxanes, pseudo-rotaxanes, catenanes, and spiropyrans.

The crossed wire switch based on the E-field induced band gap change is disclosed and claimed in patent application Ser. No. 09/823,195, filed Mar. 29, 2001, which is incorporated herein by reference. Examples of molecules used in the E-field induced band gap change approach include molecules that evidence:

(1) molecular conformation change or an isomerization;

(2) change of extended conjugation via chemical bonding change to change the band gap; or

(3) molecular folding or stretching.

Changing of extended conjugation via chemical bonding change to change the band gap may be accomplished in one of the following ways:

(2a) charge separation or recombination accompanied by increasing or decreasing band localization; or

(2b) change of extended conjugation via charge separation or recombination and π-bond breaking or formation.

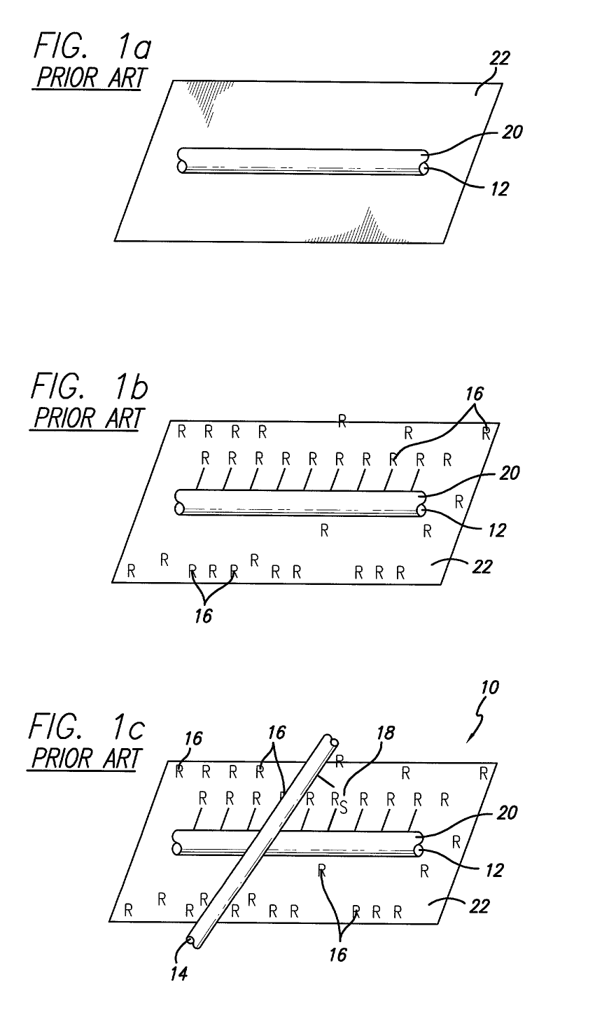

Although the description of FIGS. 1a-1c is presented in terms of the redox reaction approach, it will be readily apparent to those skilled in this art that the teachings of the present invention are equally applicable to the E-field induced band gap change approach.

The essential device features of a crossed wire switch 10 are shown in FIG. 1c. The crossed wire switch 10 comprises two wires, or electrodes, 12, 14, each either a metal or semiconductor wire, that are crossed at some non-zero angle. In between those wires is a layer of molecules or molecular compounds 16, denoted R in FIGS. 1b-1c. The particular molecules 18 (denoted Rₛ) that are sandwiched at the intersection of the two wires 12, 14 are identified as switch molecules. When an appropriate voltage is applied across the wires, the switch molecules are either oxidized or reduced. When a molecule is oxidized (reduced), then a second species is reduced (oxidized) so that charge is balanced. These two species are then called a redox pair. One example of this device would be for one molecule to be reduced, and then a second molecule (the other half of the redox pair) is oxidized. In another example, a molecule is reduced, and one of the wires is oxidized. In a third example, a molecule is oxidized, and one of the wires is reduced. In a fourth example, one wire is oxidized, and an oxide associated with the other wire is reduced. In all cases, oxidation or reduction will affect the tunneling distance or the tunneling barrier height between the two wires, thereby exponentially altering the rate of charge transport across the wire junction, and serving as the basis for a switch.

Devices 10 (micrometer scale, sub-micrometer scale, or nanometer scale) made from redox pairs may be prepared according to the method depicted in FIGS. 1a-1c. In this case, a semiconductor (i.e., silicon) nanowire 12, possibly with an insulating surface layer 20 (for silicon, this is the naturally occurring SiOₓ, where x=1-2) is deposited on a substrate 22, as illustrated in FIG. 1a. The substrate 22 is electrically insulating, and may comprise any of the substrate materials commonly employed in semiconductor fabrication, such as, but not limited to, undoped (i.e., intentionally not doped) semiconductor, silicon nitride, amorphous silicon dioxide (i.e., glass), crystalline silicon dioxide (i.e., quartz), sapphire, and the like, either in bulk form (the entire substrate) or in film form (film grown or deposited on a semiconductor substrate, such as silicon, gallium arsenide, etc.).

Second, a redox pair of molecules 16 (labeled R in FIG. 1b) is transferred as either a Langmuir-Blodgett film, or via some other form of deposition such as vacuum sublimation. The redox pair 16 can cover both the wire 12 and the substrate 22.

In the last step, either a metal or a semiconductor nanowire 14, possibly with an insulating layer (not shown), is deposited across the first wire 12. Only those redox pairs 18 that are sandwiched between the two wires 12, 14 are defined, or can function, as molecular switches 10, as illustrated in FIG. 1c.

In one approach, the silicon nanowire 12 is first formed as a layer on the substrate 22, and is subsequently patterned into individual electrodes. In particular, amorphous silicon is first deposited on the substrate 22, is converted into polycrystalline silicon (“polysilicon”), and then patterned. Alternatively, the silicon layer 12 can be patterned before crystallization.

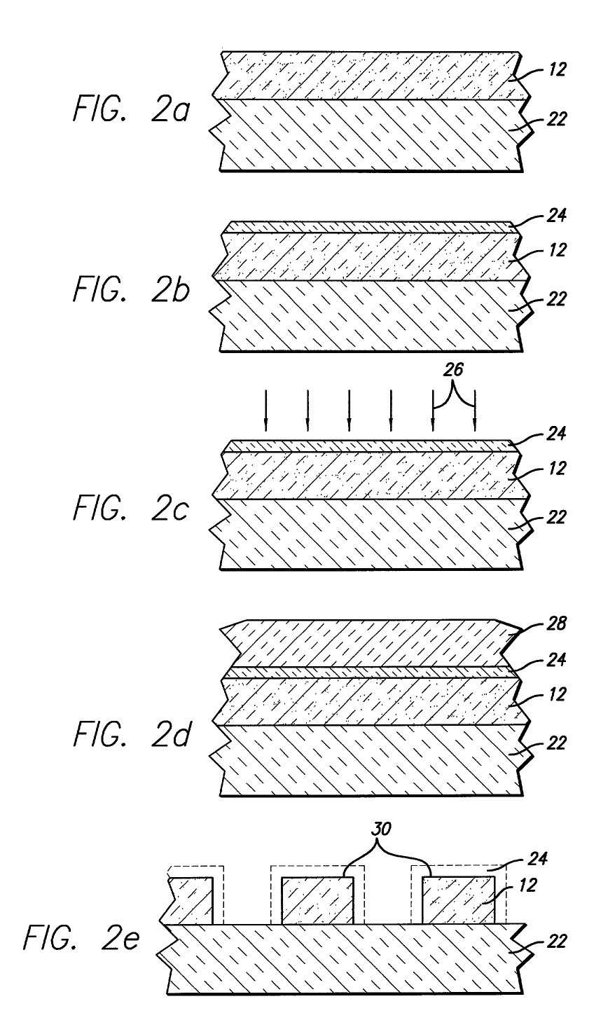

The process steps are depicted in FIGS. 2a-2e, wherein FIG. 2a illustrates formation of a silicon layer 12 on the substrate 22, FIG. 2b illustrates forming a native oxide 24 on the silicon layer, followed by conversion to polysilicon, FIG. 2c illustrates doping the polysilicon with dopant atoms 26, FIG. 2d illustrates formation of a protective layer 28 to aid in activating the dopant atoms, and FIG. 2e illustrates patterning the silicon layer to form electrodes 30.

To convert the amorphous silicon to the higher-conductivity polycrystalline silicon, the amorphous film 12 can be heat-treated (e.g., 650° C. for several hours or at higher temperatures for shorter periods) in an inert (e.g., nitrogen) ambient.

If the surface of the amorphous silicon layer 12 is very clean (e.g., free of native oxide), the silicon atoms on the surface can move during the crystallization process, and the surface becomes rough. However, a thin native oxide 24 (FIG. 2b) formed by exposing the deposited amorphous silicon film to air for a short period of time (e.g., a fraction of one hour) stabilizes the surface adequately during the crystallization process so that the surface of the resulting polycrystalline film remains smooth and suitable for use as an electrode for molecular electronics.

Specifically, a method of forming smooth polycrystalline silicon electrodes for molecular electronic devices is provided. The method comprises:

(a) depositing silicon layer 12 in an amorphous form;

(b) forming native oxide 24 on a surface of the amorphous silicon layer; and

(c) converting the amorphous silicon to polycrystalline silicon by heat-treating at a temperature in a range of 6000 to 1000° C. for a period of time in a range of 10 secs to 24 hrs, with higher temperatures associated with shorter times, in an inert atmosphere.

The silicon layer 12 is deposited in step (a) by low pressure chemical vapor deposition at a temperature in a range of about 525° to 570° C. using SiH₄. Alternatively, Si₂H₆ may be used as the source material, and the deposition temperature in that case is in the range of about 450° to 570° C. In either case, the pressure of the deposition is within a range of about 0.02 to 5 Torr, and in both cases, an amorphous layer is formed.

Alternatively, the silicon layer 12 is deposited in step (a) by reduced pressure chemical vapor deposition of between 5 and 150 Torr. At a typical temperature and total pressure of 650° C. and 80 Torr, respectively, a deposition rate of greater than 2 nm/sec is needed to obtain an amorphous layer. The suitable temperature range and deposition rate are directly related, i.e., a higher deposition rate is required at a higher temperature to obtain an amorphous layer.

In any event, the thickness of the deposited silicon layer 12 is within a range of about 10 nm to 2 μm.

Next, the native oxide 24 is formed on the amorphous silicon layer 12. This may simply be done by exposing the surface of the amorphous silicon layer to air for a period of time, even at room temperature. The time of exposure is conveniently less than 1 hr and forms a thin film of the native oxide of about 1 nm thickness.

Finally, the amorphous silicon is converted to polycrystalline silicon, employing the parameters listed above. The conversion is performed in an inert atmosphere of nitrogen, argon, or a mixture thereof. The resulting polycrystalline silicon retains the smoothness of the amorphous silicon, wherein the rms surface roughness is less than about 2% of the polycrystalline silicon film thickness.

To obtain high conductivity in the electrode, dopant atoms 26 can be implanted into the crystallized film (if they have not been added during the deposition process or before crystallization), as illustrated in FIG. 2c. After depositing a thicker protective layer 28 (e.g.,>100 nm silicon oxide), as illustrated in FIG. 2d, the silicon layer 12 is annealed at a high temperature to activate the dopant atoms. The protective layer 28 is then removed before electrode patterning or perhaps used as a part of the patterning process. The patterning can be by lithographically patterning a resist layer and etching (perhaps using the protective layer as an intermediate masking layer) or by a lift-off process, both of which are well-known processes in semiconductor processing.

As an example, phosphorus atoms may be implanted into the polycrystalline silicon film, employing a sufficient implantation energy to place a substantial fraction of the ions in the interior of the silicon film. The determination of the appropriate implantation energy is easily within the ability of the person skilled in the art. Instead of phosphorus atoms, other dopant atoms commonly used to dope silicon and thereby increase its conductivity may alternatively be employed in the practice of the present invention. Examples of such other dopant atoms include arsenic and boron.

Alternatively, dopant atoms can be added from a gas phase, such as during deposition of the amorphous silicon or during crystallization from the amorphous phase to the crystalline phase.

The dopant atoms desirably have a concentration within a range of about 1×10¹⁹ to 5×10²⁰ cm⁻³ and may be added either during the deposition of amorphous silicon or just prior to, during, or after conversion of the amorphous silicon to polycrystalline silicon.

The dopant atoms are activated by first depositing the protective layer 28 on the polycrystalline silicon 12 and then annealing the polycrystalline silicon at an elevated temperature for a period of time.

The protective layer 28 comprises a silicon oxide (SiOₓ,), formed to a thickness of at least 50 nm. SiO₂ is preferably employed, since it is generally easier to process. The maximum thickness of the protective layer is about 2 μm.

The annealing to activate the dopant atoms is performed at a temperature within a range of 800° to 1000° C. for a period of time within a range of 10 secs to 4 hrs. The longer annealing times are associated with the lower annealing temperatures. Simple experimentation on test wafers is used to determine when the dopant activation is complete; such procedure is well-known in the semiconductor processing art.

Following the annealing, the polycrystalline silicon 12 is preferably rapidly cooled, at a rate of greater than 50° C./min, to minimize dopant segregation to grain boundaries and dopant deactivation.

The polycrystalline silicon is next patterned to form electrodes 30. The patterning may be done by lithographically patterning a resist layer and etching (perhaps using the protective layer as an intermediate masking layer). Alternatively, the patterning may be done by a lift-off process. Both of these processes are conventional and well-known steps in silicon processing.

The protective layer 28 and the native oxide 24 are then removed prior to further processing to form the switch 10, as shown in FIGS. 1a-1c. FIG. 2e illustrates the patterned electrodes 30 with oxide removed. It will be appreciated that the native oxide 24 may re-form before the switch molecules 16 are added, as shown by the depiction of the native oxide 24 in phantom.

Once the patterned electrodes 30 comprising silicon electrodes 12 are formed, then the layer of switch molecules 16 may be deposited, followed by formation of the electrodes 14 to form the crossed wire switch 10.

### EXAMPLE

Poly-silicon electrodes were fabricated as follows: Low-pressure SiH₄ CVD was used to deposit 1500 Å of amorphous silicon onto 1100 Å of SiO₂ on a Si(100) wafer at 525° C. The film was exposed to air at room temperature for several minutes to form a passivating SiOₓ layer and then crystallized under nitrogen gas at 650° C. Poly-silicon films were implanted with 55 KeV P⁺ions, and a 1 μm film of SiO₂ was grown by CVD to prevent outgassing of the phosphorus. The dopant P atoms were activated at 1000° C., and then a 6:1 mixture of NH₄F(aq):HF(aq) was used to etch away the SiO₂. Electrodes were patterned by using conventional photolithography techniques.

### INDUSTRIAL APPLICABILITY

The method of forming smooth polycrystalline silicon electrodes for molecular electronic devices is expected to find use in nanoscale computing and memory circuits.

What is claimed is:

1. A method of forming smooth polycrystalline silicon electrodes for molecular electronic devices, said method comprising:
(a) depositing a silicon layer in an amorphous form;
(b) forming a native oxide on a surface of said amorphous silicon layer; and
(c) converting said amorphous silicon to polycrystalline silicon by heat-treating at a temperature in a range of 600° to 1000° C. for a period of time in a range of 10 secs to 24 hrs, with higher temperatures associated with shorter times, in an inert atmosphere.

2. The method of claim 1 wherein said amorphous silicon is deposited in step (a) by low pressure chemical vapor deposition at a temperature in a range of about 525° to 570° C. using SiH₄ or at a temperature in a range of about 450° to 570° C. using Si₂H₆.

3. The method of claim 2 wherein said low pressure chemical vapor deposition is performed at a pressure of about 0.02 to 5 Torr.

4. The method of claim 1 wherein said amorphous silicon is deposited in step (a) by reduced pressure chemical vapor deposition between 5 and 150 Torr.

5. The method of claim 1 wherein said silicon layer has a thickness within a range of about 10 nm to 2 μm.

6. The method of claim 1 wherein said native oxide is formed by exposing said surface to air for a period of time.

7. The method of claim 1 wherein said inert atmosphere employed in step (c) is selected from the group consisting of nitrogen, argon, and mixtures thereof.

8. The method of claim 1 wherein dopant atoms are implanted into said polycrystalline silicon or added from a gas phase.

9. The method of claim 8 wherein said dopant atoms have a concentration within a range of about 1×10¹⁹ to 5×10²⁰ cm⁻³.

10. The method of claim 8 wherein dopant atoms are added either during step (a) or prior to, during, or after step (c).

11. The method of claim 8 wherein said dopant atoms are activated by:
(a) depositing a protective layer on said polycrystalline silicon; and
(b) annealing said polycrystalline silicon at an elevated temperature for a period of time.

12. The method of claim 11 wherein said protective layer comprises silicon oxide (SiOₓ, where x=1-2), formed to a thickness of at least 50 nm.

13. The method of Claim II wherein said annealing is performed at a temperature within a range of 800° to 1000° C. for a period of time within a range of 10 secs to 4 hrs, with higher temperatures associated with shorter times.

14. The method of claim 11 wherein, following said annealing, said silicon electrodes are rapidly cooled, at a rate of greater than 50° C./min, to minimize dopant segregation to grain boundaries and dopant deactivation.

15. The method of claim 11 further comprising patterning said silicon layer to form said electrodes, said patterning being performed either before converting said amorphous silicon to polycrystalline silicon or subsequent thereto.

16. The method of claim 15 wherein said patterning is done by lithographically patterning a resist layer and etching.

17. The method of claim 16 wherein said protective layer is used as an intermediate masking layer.

18. The method of claim 15 wherein said patterning is done by a lift-off process.
